(19) United States
(12) Patent Application Publication
(10) Pub. No.: US 2026/0214786 A1
(43) Pub. Date: Jul. 23, 2026

(54) SIGNAL TRANSMISSION STRUCTURE FOR SIGNAL TRANSMISSION IN MULTI-LAYER CIRCUIT BOARD AND ELECTRONIC DEVICE INCLUDING THE SAME

(71) Applicant: Samsung Electronics Co., Ltd., Suwon-si (KR)

(72) Inventors: Seungyoon Jung, Suwon-si (KR); Woncheol Lee, Suwon-si (KR); Seongjung Kim, Suwon-si (KR); Doohyun Yang, Suwon-si (KR); Youngki Lee, Suwon-si (KR); Dongkwon Choi, Suwon-si (KR)

(21) Appl. No.: 19/298,041

(22) Filed: Aug. 12, 2025

(30) Foreign Application Priority Data
Jan. 23, 2025 (KR) 10-2025-0010676

(51) Int. Cl. H05K 1/02; H05K 1/11

(52) U.S. Cl. CPC H05K 1/025; H05K 1/115

(57) ABSTRACT

A signal transmission structure for signal transmission in a multi-layer circuit board and an electronic device is described. The signal transmission structure in a multi-layer circuit board includes a first layer including a first transmission line and a second layer including a second transmission line. The multi-layer circuit board further includes a waveguide configured to perform impedance matching with at least one of the first transmission line and the second transmission line. The waveguide is configured to transmit a signal transmitted from the first transmission line to the second transmission line based on a mode transition to connect the first transmission line to the second transmission line.

### CROSS-REFERENCE TO RELATED APPLICATION

This application is based on and claims priority under 35 U.S.C. § 119 to Korean Patent Application No. 10-2025-0010676, filed on Jan. 23, 2025, in the Korean Intellectual Property Office, the disclosure of which is incorporated by reference herein in its entirety.

### BACKGROUND

This disclosure relates to a signal transmission structure for signal transmission in a multi-layer circuit board and an electronic device including the same.

Recently, a fifth generation (5G) (or new radio (NR)) communication system is new radio access technology, and the purpose thereof is to provide an ultra-high speed data service of several Gbps by using an ultra-wideband having a bandwidth of 100 MHz or higher compared to existing long-term evolution (LTE) or LTE advanced (LTE-A). However, because a signal having a high frequency (e.g., mmWave or terahertz) has a large loss during transmission, it is needed to minimize the loss.

For example, a multi-layer circuit board (e.g., a printed circuit board (PCB)) may include a plurality of metal layers, and a signal moving through a line in the multi-layer circuit board may move through a via when moving between different metal layers, but there may occur impedance mismatching indicating that an impedance does not match due to various causes (e.g., a physical limit, a via pad, an unnecessary open stub, and the like) while moving through the via, thereby incurring a loss during transmission.

### SUMMARY

This disclosure provides a signal transmission structure capable of performing impedance matching with at least one of a first transmission line and a second transmission line in different layers included in a multi-layer circuit board by using a waveguide instead of a conductive via, and transmitting a signal from the first transmission line to the second transmission line based on a mode transition to connect the first transmission line to the second transmission line, and an electronic device including the same.

According to an aspect of this disclosure, there is provided a signal transmission structure for signal transmission in a multi-layer circuit board including a first layer comprising a first transmission line and a second layer comprising a second transmission line, and a waveguide configured to perform impedance matching with at least one of the first transmission line and the second transmission line and transmit a signal from the first transmission line to the second transmission line based on a mode transition.

According to another aspect of this disclosure, there is provided a signal transmission structure including a first metal layer comprising a first transmission line, a second metal layer comprising a second transmission line, and a waveguide configured to perform impedance matching with at least one of the first transmission line and the second transmission line and transmit a signal from the first transmission line to the second transmission line based on a mode transition, wherein the waveguide comprises a substrate integrated waveguide including a ground wall.

According to another aspect of this disclosure, there is provided an electronic device including a communication circuit comprising a signal transmission structure that includes a multi-layer circuit board, wherein the multi-layer circuit board comprises a first layer comprising a first transmission line and a second layer comprising a second transmission line, and at least one processor configured to execute an instruction based on a signal received from the communication circuit, wherein the multi-layer circuit board comprises a waveguide configured to perform impedance matching with at least one of the first transmission line and the second transmission line and transmit a signal from the first transmission line to the second transmission line based on a mode transition.

### BRIEF DESCRIPTION OF THE DRAWINGS

Implementations of this disclosure will be more clearly understood from the following detailed description taken in conjunction with the accompanying drawings in which:
A simple description of each drawing is provided to more sufficiently understand the drawings cited in the detailed description of this disclosure.

FIG. 1 is a perspective view illustrating a signal transmission structure according to some implementations;

FIG. 2 is a perspective view illustrating a waveguide according to some implementations;

FIGS. 3A, 3B, 3C, and 3D are block diagrams illustrating a transmission line according to some implementations;

FIGS. 4 and 5 are a perspective view and a cross-sectional view illustrating a signal transmission structure according to a comparative example;

FIG. 6 is a perspective view illustrating a signal transmission structure according to some implementations;

FIG. 7 is a cross-sectional view illustrating a signal transmission structure according to a comparative example;

FIG. 8 is a graph illustrating a signal transmission loss according to a signal transmission structure;

FIG. 9 is a cross-sectional view illustrating a signal transmission structure according to some implementations;

FIG. 10 is a cross-sectional view illustrating a signal transmission structure according to some implementations;

FIG. 11 is a block diagram illustrating an electronic device according to some implementations; and

FIG. 12 is a conceptual diagram illustrating an Internet of Things (IOT) network system to which some implementations is applied.

### DETAILED DESCRIPTION

Hereinafter, implementations are described in detail with reference to the accompanying drawings.

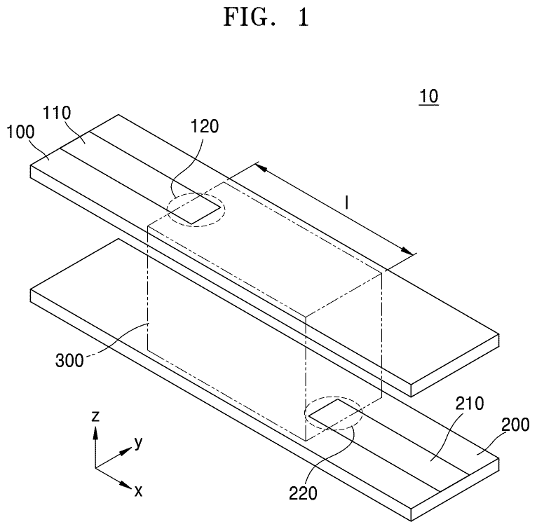

FIG. 1 is a perspective view illustrating a signal transmission structure 10 according to some implementations.

Referring to FIG. 1, the signal transmission structure 10 may include a first layer 100, a second layer 200, and a waveguide 300 but is not limited thereto. For example, the signal transmission structure 10 may include a multi-layer circuit board including a plurality of layers and further include other layers different from the first layer 100 and the second layer 200. The multi-layer circuit board may be a printed circuit board (PCB). The signal transmission structure 10 may be a three-dimensional structure and may be represented using a Cartesian coordinate system. For example, the Cartesian coordinate system may have the X axis, the Y axis, and the Z axis having a direction angle of 90 degrees therebetween.

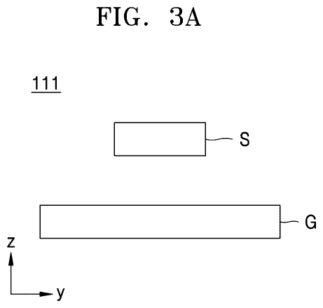

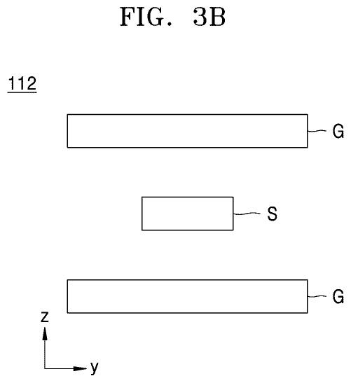

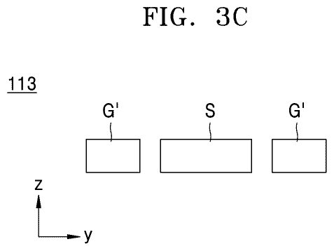

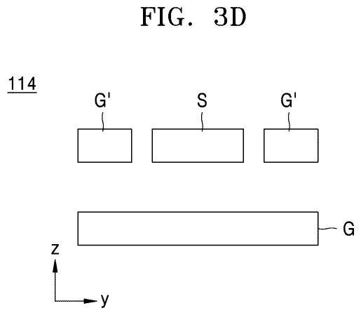

In some implementations, the first layer 100 may include a first transmission line 110, and the second layer 200 may include a second transmission line 210. The first transmission line 110 and the second transmission line 210 may indicate lines for transmitting a signal. For example, each of the first transmission line 110 and the second transmission line 210 may include at least one of a microstrip, a stripline, a co-planar waveguide (CPW), or a grounded co-planar waveguide (GCPW). A detailed example of each transmission line is described below with reference to FIGS. 3A, 3B, 3C, and 3D.

In some implementations, the first layer 100 and the second layer 200 may be formed of a metal, and the first layer 100 may be located in a different layer from the second layer 200. For example, the first layer 100 may be a higher layer than the second layer 200 in the Z-axis direction. Although FIG. 1 shows that no layer is between the first layer 100 and the second layer 200, this disclosure is not limited thereto. For example, at least one layer may be further included between the first layer 100 and the second layer 200. In addition, the signal transmission structure 10 may further include a layer higher than the first layer 100 in the Z-axis direction and a layer lower than the second layer 200 in the Z-axis direction.

The waveguide 300 may indicate a transmission medium for transmitting a signal (e.g., an electromagnetic wave) from one place to another place, have a closed structure made of a metal or a dielectric, and transmit the electromagnetic wave through reflection and interference therein. In some implementations, the waveguide 300 may be formed in various shapes. For example, the waveguide 300 may be formed in a rectangular shape formed of a metal, a circular shape formed of a metal, or a shape formed of a dielectric.

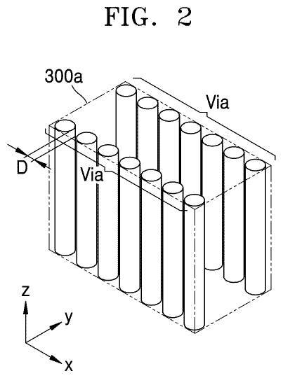

For example, the waveguide 300 may be a substrate integrated waveguide (SIW) including an upper metal plate (e.g., the first layer 100) of a substrate (e.g., the multi-layer circuit board), a lower metal plate (e.g., the second layer 200) of the substrate, and a ground wall connecting the upper and lower metal plates of the substrate. The ground wall may include a plurality of vias or a plurality of solder balls connecting the upper and lower metal plates of the substrate or may include a metal plate. Some particular implementations of the SIW including the ground wall including the plurality of vias is described below with reference to FIG. 2.

The waveguide 300 may perform impedance matching with at least one of the first transmission line 110 and the second transmission line 210. The impedance matching may indicate an operation performed to minimize reflection of a signal in a circuit.

In some implementations, the first layer 100 may include a first transition region 120 for the impedance matching, and the second layer 200 may include a second transition region 220 for the impedance matching.

For example, the first transition region 120 and the second transition region 220 may be formed to have a tapering structure. The tapering structure is a structure for impedance matching between a transmission line and a waveguide and may indicate a structure of smoothly connecting the characteristic of the transmission line to the characteristic of the waveguide through a gradually changing cross-section.

The waveguide 300 may be configured to connect transmission lines in different layers. In some implementations, the waveguide 300 may be configured to transmit a signal transmitted from the first transmission line 110 to the second transmission line 210 based on a mode transition to connect the first transmission line 110 to the second transmission line 210. For example, while a signal is transmitted through the first transmission line 110 in a transverse electromagnetic (TEM) mode, the TEM mode may be transitioned to various modes in correspondence to the geometric shape and material of the waveguide 300, and the transitioned mode may be transitioned to the TEM mode again through the second transmission line 210 such that the signal is transmitted from the first transmission line 110 to the second transmission line 210. Herein, the various modes may include any one of a transverse electric (TE)10 mode, a TE20 mode, a TE11 mode, a transverse magnetic (TM) mode, and the TEM mode.

In some implementations, the waveguide 300 may be configured to transmit a signal transmitted from the second transmission line 210 to the first transmission line 110 based on a mode transition to connect the first transmission line 110 to the second transmission line 210.

The signal transmission structure 10 according to this disclosure may perform impedance matching with at least one of the first transmission line 110 and the second transmission line 210 in different layers by using the waveguide 300 instead of a conductive via and transmit a signal transmitted from the first transmission line 110 to the second transmission line 210 based on a mode transition to connect the first transmission line 110 to the second transmission line 210, and thus, the first transmission line 110 may not be in physical contact with a conductor of the second transmission line 210.

Accordingly, the signal transmission structure 10 may prevent the occurrence of impedance mismatch and reduce a signal transmission loss when a signal is transmitted between different layers.

In some implementations, a dielectric may be between the first layer 100 and the second layer 200. The dielectric may indicate an insulator having a polarity in an electric field. A section I of the waveguide 300 may indicate the size of the waveguide 300 in the X-axis direction, and when a dielectric is between the first layer 100 and the second layer 200, the section I of the waveguide 300 may be differently designed according to the dielectric constant or dielectric loss of the dielectric.

For example, when the dielectric constant or dielectric loss of the dielectric has a relatively high value (e.g., a value greater than or equal to a threshold), the section I of the waveguide 300 may be designed to have a relatively short value (e.g., a value less than a preset value), and when the dielectric constant or dielectric loss of the dielectric has a relatively low value (e.g., a value less than or equal to the threshold), the section I of the waveguide 300 may be designed to have a relatively long value (e.g., a value greater than the preset value).

FIG. 2 is a perspective view illustrating a waveguide 300a according to some implementations. In some implementations, the waveguide 300a of FIG. 2 may be an example of the waveguide 300 of FIG. 1, and the description made with reference to FIG. 1 is omitted herein.

Referring to FIG. 2, the waveguide 300a may be a rectangular-shaped SIW including an upper metal plate of a multi-layer circuit board, a lower metal plate of the multi-layer circuit board, and a ground wall connecting the upper and lower metal plates of the multi-layer circuit board.

In some implementations, the upper metal plate of the multi-layer circuit board may be the first layer 100 of FIG. 1, and the lower metal plate of the multi-layer circuit board may be the second layer 200 of FIG. 1. In some implementations, the upper metal plate of the multi-layer circuit board may be a layer higher than the first layer 100 of FIG. 1 in the Z-axis direction, and the lower metal plate of the multi-layer circuit board may be a layer lower than the second layer 200 of FIG. 1 in the Z-axis direction.

In some implementations, the ground wall may indicate two surfaces perpendicular to the Y-axis direction among the surfaces of the waveguide 300a and may include a plurality of vias Via. A gap distance D between adjacent ones of the plurality of vias Via may be so narrow that a signal having a wavelength longer than the gap distance does not leak, e.g., a signal having a maximum frequency corresponding to the minimum wavelength of the gap distance. For example, the gap distance D between adjacent ones of the plurality of vias Via may have a preset value or less, and the preset value may be determined in advance through simulation.

In some implementations, the plurality of vias Via may include at least one of a buried via and a through-hole via. For example, when the upper metal plate of the multi-layer circuit board is the first layer 100 of FIG. 1 and the lower metal plate of the multi-layer circuit board is the second layer 200 of FIG. 1, the plurality of vias Via may be buried vias.

For example, when the upper metal plate of the multi-layer circuit board is a layer higher than the first layer 100 of FIG. 1 in the Z-axis direction and the lower metal plate of the multi-layer circuit board is a layer lower than the second layer 200 of FIG. 1 in the Z-axis direction, the plurality of vias Via may be through-hole vias.

FIGS. 3A, 3B, 3C, and 3D are block diagrams illustrating transmission lines 111 to 114 according to some implementations. In some implementations, the transmission lines 111 to 114 may be examples of the first transmission line 110 and the second transmission line 210 of FIG. 1, and the description made with reference to FIG. 1 is omitted herein. The transmission lines 111 to 114 may be side views based on the plane formed by the Y axis and the Z axis of FIG. 1.

Referring to FIGS. 1 and 3A, the transmission line 111 may be a microstrip including a signal transmission conductor S on a certain layer of a multi-layer circuit board and a ground surface G under the certain layer.

For example, the signal transmission conductor S of the transmission line 111 may be located in the first layer 100, and the ground surface G of the transmission line 111 may be in a layer lower than the first layer 100 in the Z-axis direction. For example, the signal transmission conductor S of the transmission line 111 may be located in the second layer 200, and the ground surface G of the transmission line 111 may be in a layer lower than the second layer 200 in the Z-axis direction.

Referring to FIGS. 1 and 3B, the transmission line 112 may be a stripline formed in a symmetrical structure in which ground surfaces G are located above and under a certain layer of a multi-layer circuit board, the signal transmission conductor S being located in the certain layer.

For example, the signal transmission conductor S of the transmission line 112 may be located in the first layer 100, and the ground surfaces G of the transmission line 112 may be symmetrically located in layers higher and lower than the first layer 100 in the Z-axis direction. For example, the signal transmission conductor S of the transmission line 112 may be located in the second layer 200, and the ground surfaces G of the transmission line 112 may be symmetrically located in layers higher and lower than the second layer 200 in the Z-axis direction.

Referring to FIGS. 1 and 3C, the transmission line 113 may be a CPW in a structure in which the signal transmission conductor S is located in a certain layer of the multi-layer circuit board and ground conductors G′ are located at both sides of the signal transmission conductor S.

For example, the signal transmission conductor S of the transmission line 113 may be located in the first layer 100, and the ground conductors G′ of the transmission line 113 may be located in the first layer 100 at both sides of the signal transmission conductor S of the transmission line 113. For example, the signal transmission conductor S of the transmission line 113 may be located in the second layer 200, and the ground conductors G′ of the transmission line 113 may be located in the second layer 200 at both sides of the signal transmission conductor S of the transmission line 113.

Referring to FIGS. 1 and 3D, the transmission line 114 may be a GCPW formed in a structure in which the signal transmission conductor S is located in a certain layer of the multi-layer circuit board, the ground conductors G′ are located at both sides of the signal transmission conductor S, and the ground surface G is located under the certain layer.

For example, the signal transmission conductor S of the transmission line 114 may be located in the first layer 100, and the ground conductors G′ of the transmission line 114 may be located in the first layer 100 at both sides of the signal transmission conductor S of the transmission line 114. The ground surface G of the transmission line 114 may be located in a layer lower than the first layer 100 in the Z-axis direction. For example, the signal transmission conductor S of the transmission line 114 may be located in the second layer 200, and the ground conductors G′ of the transmission line 114 may be located in the second layer 200 at both sides of the signal transmission conductor S. The ground surface G of the transmission line 114 may be located in a layer lower than the second layer 200 in the Z-axis direction.

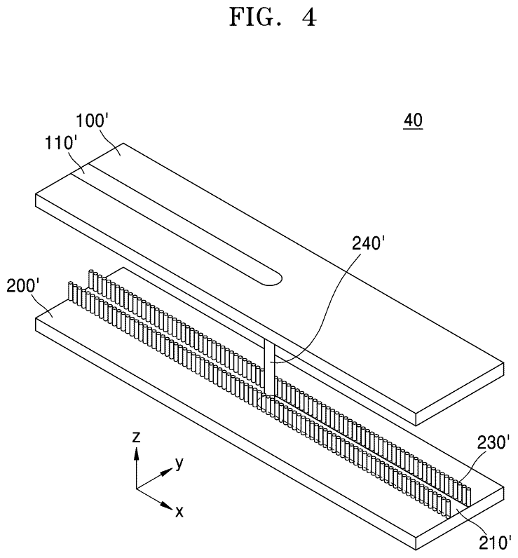

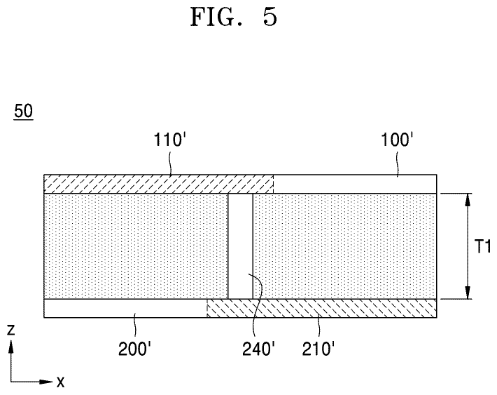

FIGS. 4 and 5 are a perspective view and a cross-sectional view illustrating a signal transmission structure according to a comparative example.

Referring to FIG. 4, a signal transmission structure 40 according to a comparative example may include a first layer 100′ and a conductive via 240′. The first layer 100′ may include a first transmission line 110′, and a second layer 200′ may include a second transmission line 210′. The first transmission line 110′ and the second transmission line 210′ may indicate lines for transmitting a signal.

The conductive via 240′ may be configured to connect transmission lines in different layers. For example, the conductive via 240′ may be configured to directly connect the first transmission line 110′ and the second transmission line 210′ through physical contact of conductors and transmit a signal from the first transmission line 110′ to the second transmission line 210′ or from the second transmission line 210′ to the first transmission line 110′.

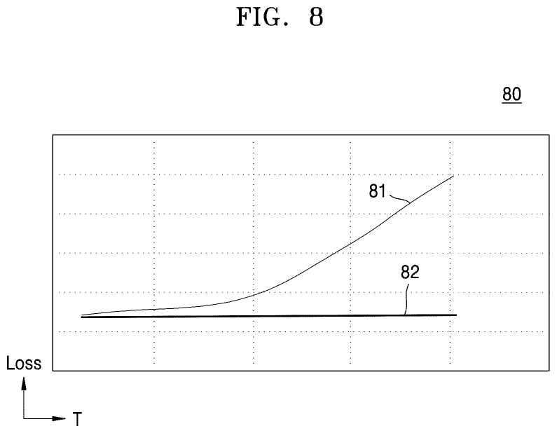

Further referring to FIG. 5, a signal transmission structure 50 according to a comparative example may be a cross-sectional view of the signal transmission structure 40 based on the plane formed by the Z axis and the X axis. A distance T1 between different layers may be the same as the length of the conductive via 240′ in the Z-axis direction, and this is described below with reference to FIG. 8.

The signal transmission structure 50 according to a comparative example performs signal transmission between different layers through the conductive via 240′, and thus, impedance mismatching may occur. To solve the impedance mismatching, impedance matching may be performed by deploying a ground via to surround the surroundings of the conductive via 240′ and adjusting clearance or performed by using a line stub on a line around the conductive via 240′. However, these impedance matching methods may be restricted due to the physical structural limitations of a multi-layer circuit board, such as the minimum width of the clearance and the position of the line stub.

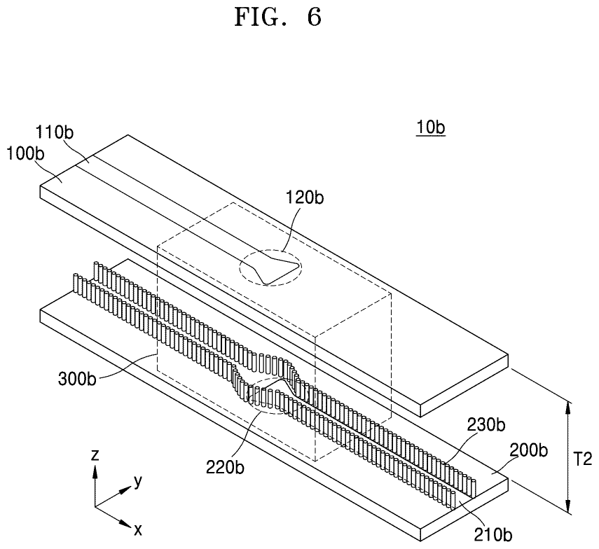

FIG. 6 is a perspective view illustrating a signal transmission structure 10b according to some implementations. In some implementations, the signal transmission structure 10b may be an example of the signal transmission structure 10 of FIG. 1, and a first layer 100b, a first transmission line 110b, a first transition region 120b, and a second transition region 220b may be the same as the first layer 100, the first transmission line 110, the first transition region 120, and the second transition region 220 of FIG. 1, respectively. The description made with reference to FIG. 1 is omitted herein.

Referring to FIG. 6, a second layer 200b may include a second transmission line 210b, the second transition region 220b, and a ground conductor 230b. In some implementations, the second transmission line 210b may be the GCPW described above with reference to FIGS. 3A, 3B, 3C, and 3D, and the ground conductor 230b may be the ground conductor G′ of the transmission line (d) of FIGS. 3A, 3B, 3C, and 3D. The ground surface G of the transmission line (d) of FIGS. 3A, 3B, 3C, and 3D may be located in a layer lower than the second layer 200b in the Z-axis direction.

In some implementations, a waveguide 300b may be a rectangular-shaped SIW including an upper metal plate of a multi-layer circuit board, a lower metal plate of the multi-layer circuit board, and a ground wall connecting the upper and lower metal plates of the multi-layer circuit board.

In some implementations, the upper metal plate of the multi-layer circuit board may be the first layer 100b, and the lower metal plate of the multi-layer circuit board may be the second layer 200b. In some implementations, the upper metal plate of the multi-layer circuit board may be a layer higher than the first layer 100b in the Z-axis direction, and the lower metal plate of the multi-layer circuit board may be a layer lower than the second layer 200b in the Z-axis direction.

In some implementations, the ground wall may indicate two surfaces perpendicular to the Y-axis direction among the surfaces of the waveguide 300b and may include a plurality of vias. The gap distance between adjacent ones of the plurality of vias may be so narrow that a signal having a wavelength greater than the gap distance does not leak, e.g., a signal has a maximum frequency corresponding to the minimum wavelength of the gap distance. For example, the gap distance between adjacent ones of the plurality of vias may have a preset value or less, and the preset value may be determined in advance through simulation.

In some implementations, the plurality of vias may include at least one of a buried via and a through-hole via. For example, when the upper metal plate of the multi-layer circuit board is the first layer 100b and the lower metal plate of the multi-layer circuit board is the second layer 200b, the plurality of vias may be buried vias. For example, when the upper metal plate of the multi-layer circuit board is a layer higher than the first layer 100b in the Z-axis direction and the lower metal plate of the multi-layer circuit board is a layer lower than the second layer 200b in the Z-axis direction, the plurality of vias may be through-hole vias.

Unlike the signal transmission structure (e.g., the signal transmission structure 40 of FIG. 4 and the signal transmission structure 50 of FIG. 5) according to a comparative example, the signal transmission structure 10b according to this disclosure performs signal transmission between the first transmission line 110b and the second transmission line 210b by using the waveguide 300b instead of a conductive via, thereby avoiding physical contact of conductors.

In other words, unlike impedance matching methods for solving impedance mismatching due to physical contact of conductors, the signal transmission structure 10b according to this disclosure may not have restrictions due to the physical structural limitations of a multi-layer circuit board, such as the minimum width of clearance and the position of a line stub, and may reduce a signal transmission loss by performing impedance matching with at least one of the first transmission line 110b and the second transmission line 210b in different layers.

A distance T2 between different layers may be the same as the length of the waveguide 300b in the Z-axis direction, and this is described below with reference to FIG. 8.

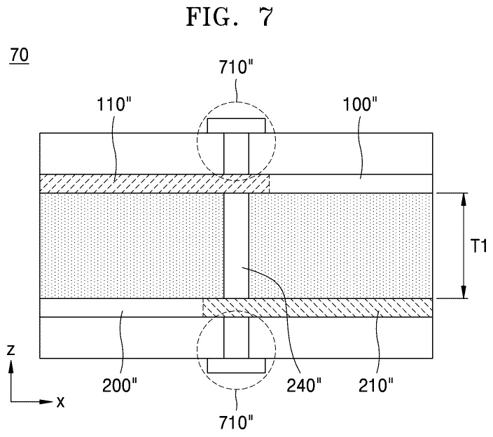

FIG. 7 is a cross-sectional view illustrating a signal transmission structure 70 according to a comparative example.

Referring to FIGS. 5 and 7, the signal transmission structure 70 according to a comparative example may be an example of the signal transmission structure 50 of FIG. 5. For example, the signal transmission structure 50 may further include a plurality of layers in addition to the first layer 100′ and the second layer 200′, and the first layer 100′ and the second layer 200′ may be inside the signal transmission structure 50. A first layer 100″, a second layer 200″, a first transmission line 110″, a second transmission line 210″, a conductive via 240″, and a distance T1 between different layers may be the same as the first layer 100′, the second layer 200′, the first transmission line 110′, the second transmission line 210′, the conductive via 240′, and the distance T1 between different layers respectively, and the description made with reference to FIG. 5 is omitted herein.

In the signal transmission structure 70 according to a comparative example, when it is impossible to produce a buried via, the conductive via 240″ may be a through-via hole, and an open stub 710″ may occur. The open stub 710″ may be a structure unnecessary for signal transmission between different layers and influence impedance matching so as to cause impedance mismatching to occur.

In addition, in the signal transmission structure 70 according to a comparative example, when the conductive via 240″ is a through-via hole, a via pad may be required for each layer, and due to the via pad, the conductive via 240″ may not be smooth in the Z-axis direction. Accordingly, the via pad may influence impedance matching so as to cause impedance mismatching to occur.

However, a signal transmission structure (e.g., 10 of FIG. 1) according to this disclosure may perform signal transmission between different layers by using a waveguide (e.g., 300 of FIG. 1) instead of a conductive via, thereby avoiding physical contact of conductors.

In other words, the signal transmission structure (e.g., 10 of FIG. 1) according to this disclosure may not cause impedance mismatching due to the open stub 710″, thereby reducing a signal transmission loss.

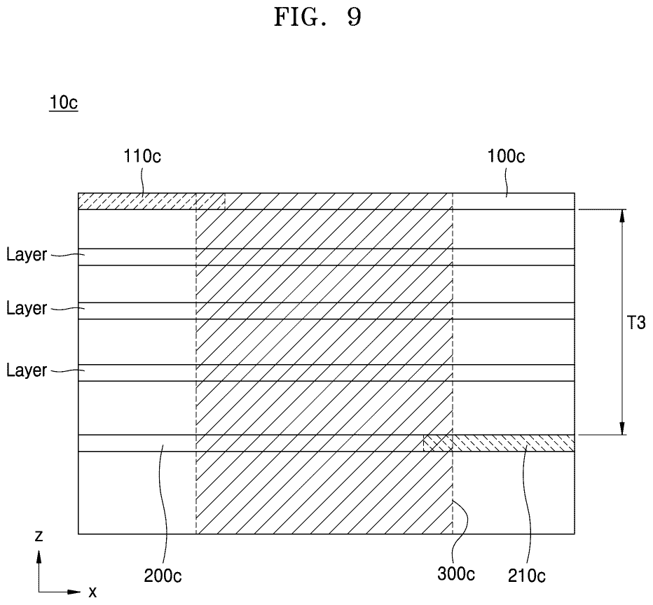

FIG. 8 is a graph 80 illustrating a signal transmission loss according to a signal transmission structure. FIG. 9 is a cross-sectional view illustrating a signal transmission structure 10c according to some implementations.

Referring to FIG. 8, the graph 80 is a graph for describing a signal transmission loss, wherein the vertical axis indicates a signal transmission loss Loss, and the horizontal axis indicates a distance T between different layers of a multi-layer circuit board. For example, the distance T between different layers may indicate the distance T1 of FIG. 5 or the distance T2 of FIG. 6.

For a signal transmission structure 81 using a conductive via (e.g., 240′ of FIG. 5) for signal transmission between different layers, as the distance T between different layers increases, the signal transmission loss Loss also increases.

However, for a signal transmission structure 82 using a waveguide (e.g., 300b of FIG. 6) for signal transmission between different layers, even if the distance T between different layers increases, the signal transmission loss Loss does not increase.

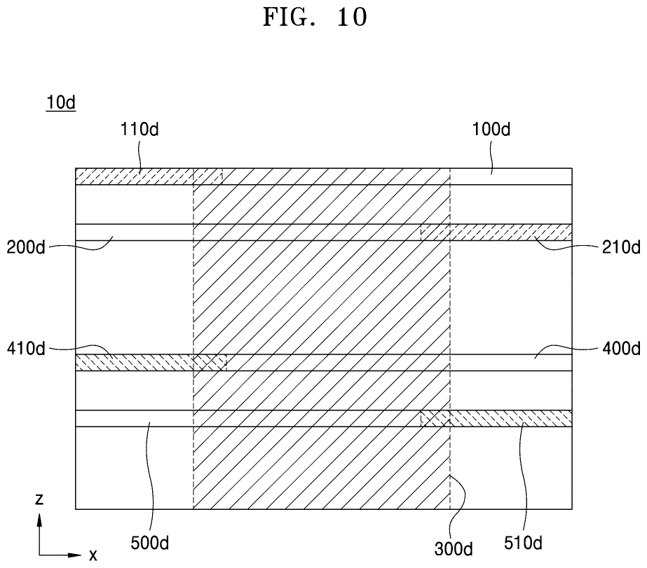

The signal transmission structure 82 may be a signal transmission structure (e.g., 10 of FIG. 1 or 10b of FIG. 6) of this disclosure, and even if the thickness of a multi-layer circuit board (e.g., the distance T between different layers) increases, a signal transmission loss may not increase. Accordingly, in signal transmission between different layers, even if a plurality of layers are included between the different layers, a signal transmission loss may not increase.

For example, referring to FIG. 9, the signal transmission structure 10c may be an example of the signal transmission structure 10 of FIG. 1, and FIG. 9 may be a plan view based on the plane formed by the Z axis and the X axis. A first layer 100c, a first transmission line 110c, a second layer 200c, a second transmission line 210c, and a waveguide 300c may be the same as the first layer 100, the first transmission line 110, the second layer 200, the second transmission line 210, and the waveguide 300 of FIG. 1, respectively.

In some implementations, the signal transmission structure 10c may further include a plurality of layers Layer between the first layer 100c and the second layer 200c. Although a distance T3 between different layers, i.e., the first layer 100c and the second layer 200c, for signal transmission may increase due to the plurality of layers Layer, the signal transmission structure 10c may perform impedance matching with at least one of the first transmission line 110c and the second transmission line 210c in the different layers by using the waveguide 300c instead of a conductive via and transmit a signal transmitted from the first transmission line 110c to the second transmission line 210c based on a mode transition to connect the first transmission line 110c to the second transmission line 210c, and thus, a signal transmission loss may not increase.

FIG. 10 is a cross-sectional view illustrating a signal transmission structure 10d according to some implementations. In some implementations, the signal transmission structure 10d may be an example of the signal transmission structure 10 of FIG. 1, and FIG. 10 may be a plan view based on the plane formed by the Z axis and the X axis. A waveguide 300d may be the same as the waveguide 300 of FIG. 1, and the description made with reference to FIG. 1 is omitted herein.

Although FIG. 10 shows that four layers are connected to one waveguide 300d, this disclosure is not limited thereto. For example, at least one layer may be further included in addition to the four layers, or only some of the four layers may be included.

A first layer 100d may include a first transmission line 110d, a second layer 200d may include a second transmission line 210d, a third layer 400d may include a third transmission line 410d, and a fourth layer 500d may include a fourth transmission line 510d. The first transmission line 110d, the second transmission line 210d, the third transmission line 410d, and the fourth transmission line 510d may indicate lines for transmitting a signal.

For example, each of the first transmission line 110d, the second transmission line 210d, the third transmission line 410d, and the fourth transmission line 510d may include at least one of a microstrip, a stripline, a CPW, or a GCPW.

In some implementations, the waveguide 300d may be configured to connect transmission lines in different layers. For example, the waveguide 300d may be configured to transmit a signal transmitted from the first transmission line 110d to the second transmission line 210d based on a mode transition or transmit a signal transmitted from the second transmission line 210d to the first transmission line 110d based on a mode transition to connect the first transmission line 110d to the second transmission line 210d.

For example, the waveguide 300d may be configured to transmit a signal transmitted from the third transmission line 410d to the fourth transmission line 510d based on a mode transition or transmit a signal transmitted from the fourth transmission line 510d to the third transmission line 410d based on a mode transition to connect the third transmission line 410d to the fourth transmission line 510d.

For example, the waveguide 300d may be configured to transmit a signal transmitted from the first transmission line 110d to the third transmission line 410d based on a mode transition or transmit a signal transmitted from the third transmission line 410d to the first transmission line 110d based on a mode transition to connect the first transmission line 110d to the third transmission line 410d.

For example, the waveguide 300d may be configured to transmit a signal transmitted from the first transmission line 110d to the fourth transmission line 510d based on a mode transition or transmit a signal transmitted from the fourth transmission line 510d to the first transmission line 110d based on a mode transition to connect the first transmission line 110d to the fourth transmission line 510d.

For example, the waveguide 300d may be configured to transmit a signal transmitted from the second transmission line 210d to the fourth transmission line 510d based on a mode transition or transmit a signal transmitted from the fourth transmission line 510d to the second transmission line 210d based on a mode transition to connect the second transmission line 210d to the fourth transmission line 510d.

In some implementations, the waveguide 300d may be configured to connect transmission lines in a plurality of different layers. For example, the waveguide 300d may be configured to transmit a signal transmitted from the first transmission line 110d to the second transmission line 210d based on a mode transition or transmit a signal transmitted from the second transmission line 210d to the first transmission line 110d based on a mode transition to connect the first transmission line 110d to the second transmission line 210d, and configured to transmit a signal transmitted from the third transmission line 410d to the fourth transmission line 510d based on a mode transition or transmit a signal transmitted from the fourth transmission line 510d to the third transmission line 410d based on a mode transition to connect the third transmission line 410d to the fourth transmission line 510d, such that the signal transmissions do not collide with each other.

Accordingly, the signal transmission structure 10d of this disclosure may perform one or more signal transmissions in parallel.

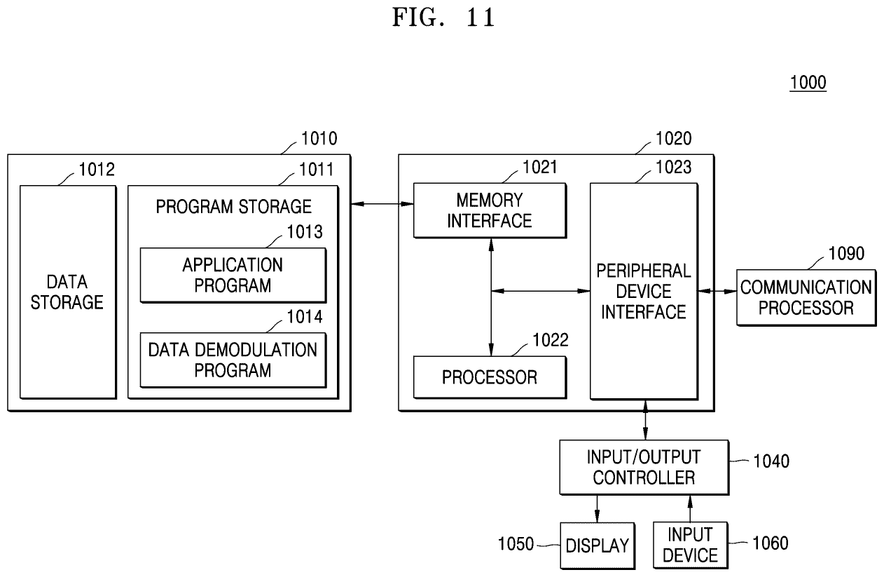

FIG. 11 is a block diagram illustrating an electronic device 1000 according to some implementations.

Referring to FIG. 11, the electronic device 1000 may include a memory 1010, a processor unit 1020, an input/output controller 1040, a display 1050, an input device 1060, and a communication processor 1090. Herein, the memory 1010 may exist in plurality. Each component is described below.

The memory 1010 may include a program storage 1011 storing a program for controlling an operation of the electronic device 1000 and a data storage 1012 storing data generated while executing the program. The data storage 1012 may store data required for operations of an application program 1013 and a data demodulation program 1014 or data generated by the operations of the application program 1013 and the data demodulation program 1014.

The program storage 1011 may include the application program 1013 and the data demodulation program 1014. Herein, a program included in the program storage 1011 is a set of instructions and may be represented as an instruction set. The application program 1013 may include program code for executing various applications operating in the electronic device 1000. That is, the application program 1013 may include code (or commands) related to various applications driven by a processor 1022.

The electronic device 1000 may include the communication processor 1090 configured to perform a communication function for voice communication and data communication. A peripheral device interface 1023 may control connections among the input/output controller 1040, the communication processor 1090, the processor 1022, and a memory interface 1021. The processor 1022 may use at least one software program to control the electronic device 1000 to provide a corresponding service. In this case, the processor 1022 may provide a service corresponding to a corresponding program by executing at least one program stored in the memory 1010.

The input/output controller 1040 may provide an interface between input/output devices, such as the display 1050 and the input device 1060, and the peripheral device interface 1023. The display 1050 displays state information, an input character, a moving picture, a still picture, and the like. For example, the display 1050 may display information on an application program driven by the processor 1022.

The input device 1060 may provide input data generated by a selection on the electronic device 1000 to the processor unit 1020 through the input/output controller 1040. Herein, the input device 1060 may include a keypad including at least one hardware button, a touch pad configured to sense touch information, and the like. For example, the input device 1060 may provide touch information, such as a touch, a touch motion, or a touch release, sensed through the touch pad to the processor 1022 through the input/output controller 1040.

The communication processor 1090 may include one of the signal transmission structures 10, 10b, 10c, and 10d described above with reference to FIGS. 1, 2, 3A, 3B, 3C, and 3D, 6 and 8 to 10. For example, the communication processor 1090 may include a multi-layer circuit board, perform impedance matching with at least one of the transmission lines in different layers included in the multi-layer circuit board by using a waveguide instead of a conductive via, and transmit a signal transmitted from a certain transmission line to another transmission line based on a mode transition to connect the transmission lines different from each other. Accordingly, the occurrence of impedance mismatching may be prevented, and when a signal is transmitted between different layers, a signal transmission loss may be reduced.

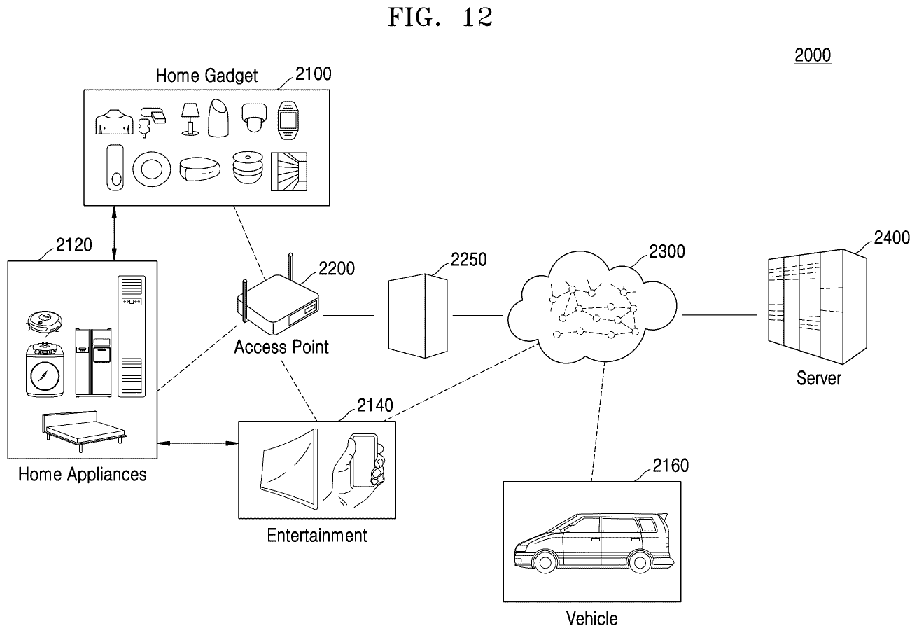

FIG. 12 is a conceptual diagram illustrating an Internet of Things (IOT) network system 2000 to which some implementations is applied.

Referring to FIG. 12, the IoT network system 2000 may include a plurality of IoT devices 2100, 2120, 2140, and 2160, an access point 2200, a gateway 2250, a radio network 2300, and a server 2400. IoT may indicate a network among things using wired/wireless communication.

The plurality of IoT devices 2100, 2120, 2140, and 2160 may be grouped according to the characteristics thereof. For example, the plurality of IoT devices 2100, 2120, 2140, and 2160 may be grouped to a home gadget group 2100, a home appliance/furniture group 2120, an entertainment group 2140, and a vehicle group 2160. The plurality of IoT devices 2100, 2120, 2140, and 2160 may be connected to a communication network or another IoT device through the access point 2200. The access point 2200 may be embedded in one IoT device. The gateway 2250 may change a protocol to connect the access point 2200 to an external radio network. The IoT devices 2100, 2120, and 2140 may be connected to an external communication network through the gateway 2250. The radio network 2300 may include the Internet and/or a public network. The plurality of IoT devices 2100, 2120, 2140, and 2160 may be connected, through the radio network 2300, to the server 2400 that provides a certain service, and a user may use the certain service through at least one of the plurality of IoT devices 2100, 2120, 2140, and 2160.

The plurality of IoT devices 2100, 2120, 2140, and 2160 may include one of the signal transmission structures 10, 10b, 10c, and 10d described above with reference to FIGS. 1, 2, 3A, 3B, 3C, 3D, 6, and 8 to 10. For example, the communication processor 1090 may include a multi-layer circuit board, perform impedance matching with at least one of the transmission lines in different layers included in the multi-layer circuit board by using a waveguide instead of a conductive via, and transmit a signal transmitted from a certain transmission line to another transmission line based on a mode transition to connect the transmission lines different from each other. Accordingly, the occurrence of impedance mismatching may be prevented, and when a signal is transmitted between different layers, a signal transmission loss may be reduced.

As used herein, the term “at least one of” can refer to and encompass any and all possible combinations of one or more of the associated listed terms. For example, the term “at least one of A, B, or C” means that (i) at least one of A, (ii) at least one of B, (iii) at least one of C, (iv) at least one of A and at least one of B, (v) at least one of B and at least one of C, (vi) at least one of A and at least one of C, or (vi) at least one of A, at least one of B and at least one of C are possible, where A, B and C may be singular or plural.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While this disclosure has been particularly shown and described with reference to implementations thereof, it will be understood that various changes in form and details may be made therein without departing from the spirit and scope of the following claims.

What is claimed is:

1. A signal transmission structure for signal transmission in a multi-layer circuit board comprising:
a first layer comprising a first transmission line;
a second layer comprising a second transmission line; and
a waveguide configured to
perform impedance matching with at least one of the first transmission line and the second transmission line, and
transmit a signal from the first transmission line to the second transmission line based on a mode transition.

2. The signal transmission structure of claim 1, wherein the waveguide comprises a substrate integrated waveguide including a ground wall.

3. The signal transmission structure of claim 2, wherein the ground wall of the substrate integrated waveguide comprises a plurality of vias, a plurality of solder balls, or both the plurality of vias and the plurality of solder balls.

4. The signal transmission structure of claim 2, wherein the ground wall comprises a plurality of vias, and wherein a gap distance between adjacent ones of the plurality of vias has a preset value or less, wherein the preset value is based on a minimum wavelength of the signal.

5. The signal transmission structure of claim 2, wherein the ground wall comprises a plurality of vias, and wherein the plurality of vias comprises a buried via, a through-hole via or both the buried via and the through-hole via.

6. The signal transmission structure of claim 5, wherein
the multi-layer circuit board comprises a third layer including a third transmission line and a fourth layer including a fourth transmission line,
the plurality of vias comprise a through-via hole, and
the waveguide is configured to transmit an additional signal from the third transmission line to the fourth transmission line based on an additional mode transition.

7. The signal transmission structure of claim 6, wherein the first layer and the second layer are located higher than the third layer and the fourth layer.

8. The signal transmission structure of claim 1, wherein the first layer, the second layer, or both the first layer and the second layer comprise a transition region configured to perform the impedance matching.

9. The signal transmission structure of claim 8, wherein the transition region comprises a tapering structure.

10. The signal transmission structure of claim 1, wherein each of the first transmission line and the second transmission line comprises at least one of a microstrip, a stripline, a co-planar waveguide, or a grounded co-planar waveguide.

11. A signal transmission structure comprising:
a first metal layer comprising a first transmission line;
a second metal layer comprising a second transmission line; and
a waveguide configured to
perform impedance matching with at least one of the first transmission line and the second transmission line, and
transmit a signal from the first transmission line to the second transmission line based on a mode transition,
wherein the waveguide comprises a substrate integrated waveguide including a ground wall.

12. The signal transmission structure of claim 11, wherein
the ground wall comprises a plurality of vias, and
a gap distance between adjacent ones of the plurality of vias has a preset value or less, wherein the preset value is based on a minimum wavelength of the signal.

13. The signal transmission structure of claim 11, comprising:
a third metal layer including a third transmission line; and
a fourth metal layer including a fourth transmission line,
wherein the ground wall includes a plurality of through-hole vias, and
the waveguide is configured to transmit an additional signal from the third transmission line to the fourth transmission line based on an additional mode transition.

14. The signal transmission structure of claim 13, wherein the first metal layer and the second metal layer are located higher than the third metal layer and the fourth metal layer.

15. The signal transmission structure of claim 11, wherein
the first metal layer, the second metal layer, or both the first metal layer and the second metal layer comprise a transition region configured to perform the impedance matching, and
the transition region comprises a tapering structure.

16. The signal transmission structure of claim 11, wherein
each of the first transmission line and the second transmission line comprises at least one of a microstrip, a stripline, a co-planar waveguide, or a grounded co-planar waveguide.

17. An electronic device comprising:
a communication circuit comprising a signal transmission structure that includes a multi-layer circuit board, wherein the multi-layer circuit board comprises a first layer comprising a first transmission line and a second layer comprising a second transmission line; and
at least one processor configured to execute an instruction based on a signal received from the communication circuit,
wherein the multi-layer circuit board comprises
a waveguide configured to
perform impedance matching with at least one of the first transmission line and the second transmission line, and
transmit a signal from the first transmission line to the second transmission line based on a mode transition.

18. The electronic device of claim 17, wherein the waveguide is a substrate integrated waveguide comprising a ground wall.

19. The electronic device of claim 18, wherein
the ground wall comprises a plurality of vias,
the plurality of vias comprise a buried via, a through-hole via, or both a buried via and a through-hole via, and
a gap distance between adjacent ones of the plurality of vias has a preset value or less, wherein the preset value is based on a minimum wavelength of the signal.

20. The electronic device of claim 19, wherein
the multi-layer circuit board comprises a third layer including a third transmission line and a fourth layer including a fourth transmission line,
the plurality of vias comprises a through-hole via, and
the waveguide is configured to transmit an additional signal from the third transmission line to the fourth transmission line based on an additional mode transition.
